(19) United States
(12) Patent Application Publication
(10) Pub. No.: US 2017/0200841 A1
(43) Pub. Date: Jul. 13, 2017

(54) PHOTOELECTRIC CONVERSION ELEMENT HAVING QUANTUM STRUCTURE USING INDIRECT TRANSITION CONDUCTOR MATERIAL

(71) Applicants: Sharp Kabushiki Kaisha, Osaka (JP); The University of Tokyo, Tokyo (JP)

(72) Inventors: Hirofumi YOSHIKAWA, Sakai City (JP); Makoto IZUMI, Sakai City (JP); Yasuhiko ARAKAWA, Bunkyo-ku (JP); Katsuyuki WATANABE, Bunkyo-ku (JP)

(21) Appl. No.: 15/378,088

(22) Filed: Dec. 14, 2016

(30) Foreign Application Priority Data
Jan. 12, 2016 (JP) 2016-003963

(51) Int. Cl. H01L 31/0352; H01L 31/109; H01L 31/0735; H01L 31/0304

(52) U.S. Cl. CPC H01L 31/035236; H01L 31/03046; H01L 31/035218; H01L 31/109; H01L 31/0735

(57) ABSTRACT

A photoelectric conversion element includes a photoelectric conversion layer having the quantum structure and utilizes intersubband transition in a conduction band. The photoelectric conversion element includes a superlattice semiconductor layer in which a barrier layer and a quantum dot layer as a quantum layer are alternately and repeatedly stacked. The barrier layer includes an indirect transition semiconductor material, and the quantum dot layer has a nano-structure including a direct transition semiconductor material. The indirect transition semiconductor material constituting the barrier layer has a bandgap of more than 1.42 eV at room temperature.

### BACKGROUND

1. Field

The present disclosure relates to a photoelectric conversion element.

2. Description of the Related Art

Examples of a Photoelectric conversion element provided with a photoelectric conversion layer include a solar cell and a photosensor (photodetector). Various researches and developments of solar cells are carried out for the purpose of increasing the photoelectric conversion efficiency by using light within a wider wavelength region. For example, there is proposed a solar cell in which electrons are photo-excited in two steps through a quantum level (including a superlattice miniband or an intermediate band) formed between the valence band and the conduction band of a matrix material, and thus light at a long wavelength can be utilized (refer to Japanese Unexamined Patent Application Publication (Translation of PCT Application) No. 2010-509772 and PHYSICAL REVIEW LETTERS, vol. 97, p. 247701, 2006).

Such a solar cell having quantum dots is a compound solar cell in which a quantum dot layer containing quantum dots is inserted. When a quantum dot layer is inserted into a base semiconductor, absorption of light within an unused wavelength region (absorption of photon with smaller energy than the bandgap of the matrix material) can be realized by photoexcitation in two steps through a quantum level, and thus photocurrent can be increased. Typically, GaAs having a bandgap of 1.42 eV at room temperature is used as the base semiconductor. Also, research and development of a quantum dot photosensor having quantum dots are carried out for increasing sensitivity. For example, there is proposed a quantum dot photosensor utilizing transition through a quantum level in a conduction band for increasing sensitivity within the middle- and far-infrared region.

### SUMMARY

At present, a solar cell in which a quantum dot layer is inserted has a very low efficiency of extraction of carriers in the quantum dot layer and thus shows sluggish improvement in photoelectric conversion efficiency. One conceivable cause for this is the low efficiency of two-step light absorption through a quantum level (including a superlattice miniband or an intermediate band). In particular, there become problems that a spectrum of absorption from the quantum level to the conduction band, which corresponds to light absorption in the second step in the two-step light absorption, has low matching with a solar light spectrum (because of the weak quantum confinement effect), and that the carriers exited to the conduction band are relaxed to the quantum level and recombined (because of the low efficiency of carrier extraction). A quantum dot photosensor also has a problem of increasing the sensitivity resulting from the weak quantum enhancement effect and the low efficiency of carrier extraction.

It is desirable to provide a technique for improving the photoelectric conversion efficiency of a photoelectric conversion element.

According to an aspect of the disclosure, there is provided a photoelectric conversion element having a quantum structure using an indirect transition semiconductor material, the photoelectric conversion element utilizing intersubband transition in a conduction band and including a photoelectric conversion layer which has the quantum structure. The photoelectric conversion element further includes a superlattice semiconductor layer in which a barrier layer and a quantum layer are alternately and repeatedly stacked. The barrier layer is composed of an indirect transition semiconductor material, and the quantum layer has a nano-structure composed of a direct transition semiconductor material, the indirect transition semiconductor material having a bandgap of more than 1.42 eV at room temperature.

### BRIEF DESCRIPTION OF THE DRAWINGS

FIG. 1 is a schematic sectional view showing a configuration of a solar cell according to an embodiment;

FIG. 2 is a diagram showing a relationship between the height of quantum dots and energy gap between e0 and e1 calculated for a superlattice semiconductor layer in Experimental Example 1;

FIG. 3 is a diagram showing an intersubband light absorption spectrum of a conduction band calculated for a superlattice semiconductor layer in Experimental Example 2;

FIG. 4 is a diagram showing a relationship between the height of quantum dots and energy gap between e0 and e1 calculated for a superlattice semiconductor layer in Comparative Experimental Example 1; and

FIG. 5 is a diagram showing an intersubband light absorption spectrum of a conduction band calculated for a superlattice semiconductor layer in Comparative Experimental Example 2.

### DESCRIPTION OF THE EMBODIMENTS

A photoelectric conversion element having a quantum structure using an indirect transition semiconductor material according to an embodiment of the present disclosure includes a photoelectric conversion layer which has the quantum structure and utilizes intersubband transition in a conduction band. The photoelectric conversion element further includes a superlattice semiconductor layer in which a barrier layer and a quantum layer are alternately and repeatedly stacked. The barrier layer is composed of an indirect transition semiconductor material, and the quantum layer has a nano-structure composed of a direct transition semiconductor material, the indirect transition semiconductor material having a bandgap of more than 1.42 eV at room temperature (first configuration).

According to the first configuration, the quantum confinement effect is enhanced by using, as a material of the barrier layer, the semiconductor material having a bandgap of more than 1.42 eV at room temperature. In addition, the extraction efficiency of carriers exited to the conduction band is improved by using the indirect transition semiconductor material as a material for the barrier layer. Therefore, the photoelectric conversion efficiency can be improved.

In the first configuration, the superlattice semiconductor layer may be doped with an impurity (second configuration).

According to the second configuration, intersubband transition can be efficiently induced, and thus the photoelectric conversion efficiency can be further improved.

In the first or second configuration, the quantum layer may be a quantum dot layer having quantum dots (third configuration).

In the third configuration, the quantum dot layer may contain the quantum dots and a cap, the quantum dots may contain In, and the cap may contain InₓGa₁₋ₓAs (0≦x≦1) (fourth configuration).

In the first to fourth configurations, the indirect transition semiconductor material may contain at least one of Al and P (fifth configuration).

Any one of the first to fifth configurations may further include a substrate composed of GaAs (sixth configuration).

### Embodiment

An embodiment of the present disclosure is described in detail below with reference to the drawings. The same portion or corresponding portions are denoted by the same reference numeral, and description thereof is not repeated. In order to make the description easy to understand, the drawings referred to below each show a simplified or illustrated configuration, or some of the constituent members are omitted. Also, the dimensional ratio between the constituent members shown in each of the drawings is not necessarily an actual dimensional ratio.

The terms used in the specification are briefly described here. However, the terms are described with respect to a configuration of the embodiment, and the present disclosure is not limited to the description of the terms.

The term “quantum layer” represents a quantum dot layer, a quantum nanowire layer, a quantum well layer, or the like, which includes a semiconductor material having a narrower bandgap than that of the semiconductor material constituting the barrier layer and has a discrete energy level due to a quantum effect. In the embodiment, a combination of the quantum dots and a cap of the quantum dots is referred to as the quantum dot layer.

The term “nanostructure” represents a quantum dot, a quantum nanowire, a quantum well, or the like.

The term “quantum dot” represents a semiconductor fine particle having a particle size of 100 nm or less and a fine particle surrounded by a semiconductor material having a larger bandgap than that of a semiconductor material constituting quantum dots.

The term “barrier layer” represents a layer including a base semiconductor material having a larger bandgap than that of a semiconductor material constituting a quantum layer and when the quantum layer is a quantum dot layer, the barrier layer does not contain quantum dots.

The term “quantum level” represents a discrete energy level.

The term “superlattice structure” represents a quantum structure including crystal lattices having a periodic structure longer than a basic unit lattice because of overlapping of a plurality of types of crystal lattices.

The term “superlattice semiconductor layer” represents a layer having a superlattice structure formed by stacking a barrier layer and a quantum layer repeatedly a plurality of times. Both the barrier layer and the quantum layer are made of a compound semiconductor material.

The term “intersubband transition in a conduction band” represents the transition from a quantum level in a conduction band to another quantum level in the conduction band higher than the energy position of the transition origin or to a conduction band of a matrix material (including a level at an energy position which is higher than the lower end of the conduction band of the matrix material and is affected by the quantum confinement effect).

A description is made below of an example in which a photoelectric conversion element is applied to a solar cell.

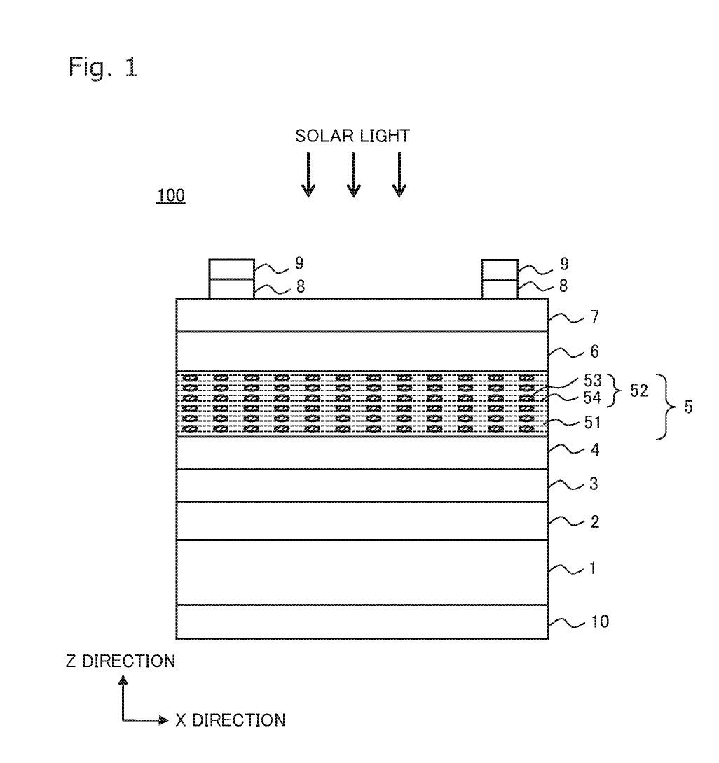

FIG. 1 is a schematic sectional view showing a configuration of a solar cell according to an embodiment. A solar cell 100 according to an embodiment includes a substrate 1, a buffer layer 2, a BSF (Back Surface Field) layer 3, a base layer 4, a superlattice semiconductor layer 5, an emitter layer 6, a window layer 7, a contact layer 8, a p-type electrode 9, and an n-type electrode 10.

Specifically, the buffer layer 2, the BSF layer 3, and the base layer 4 are formed in order on the substrate 1, and the superlattice semiconductor layer 5 is formed on the base layer 4. In addition, the emitter layer 6 is formed on the superlattice semiconductor layer 5, and the window layer 7 is formed on the emitter layer 6. The p-type electrode 9 is formed on the window layer 7 with the contact layer 8 provided therebetween. Of the both surfaces of the substrate 1, the surface (back surface) opposite to the side on which the buffer layer 2 is formed is provided with the n-type electrode 10.

In the solar cell 100 shown in FIG. 1, the side provided with the p-type electrode 9 is the solar light receiving surface side. Therefore, in the solar cell 100 of the embodiment, the surface on the side provided with the p-type electrode 9 is referred to as the “light receiving surface”, and the surface on the side provided with the n-type electrode 10 is referred to as the “back surface”.

The substrate 1 includes a semiconductor containing an n-type impurity.

The buffer layer 2 is composed of, for example, n⁺-GaAs and has a thickness of, for example, 100 nm to 500 nm.

The BSF layer 3 is composed of, for example, n-Al_{0.9}Ga_{0.1}As and has a thickness of, for example, 10 nm to 300 nm.

The base layer 4 includes a semiconductor containing an n-type impurity and is composed of GaAs, AlGaAs, InGaP, GaAsP, AlGaAsSb, AlAsSb, GaAsSb, InAlAs, ZnTe, or the like. The base layer 4 may be formed by adding an n-type impurity to the same semiconductor material as a barrier layer 51 described below or adding an n-type impurity to a semiconductor material different from the barrier layer 51. The concentration of the n-type impurity in the base layer 4 is not particularly limited and may be properly determined according to the semiconductor material constituting the base layer 4.

The base layer 4 includes a thin film formed by a CVD (Chemical Vapor Deposition) method a MBE (Molecular Beam Epitaxy) method, or the like. The thickness of the base layer 4 is, for example, 20 nm to 3000 nm. However, the thickness of the base layer 4 is not particularly limited and may be properly determined so that the superlattice semiconductor layer 5 can sufficiently absorb light.

Although, in FIG. 1, the base layer 4 is disposed on the side opposite to the light incident side of the superlattice semiconductor layer 5, the base layer 4 may be disposed on the light incident side.

The superlattice semiconductor layer 5 is disposed between the base layer 4 and the emitter layer 6. The superlattice semiconductor layer 5 has a superlattice structure in which the barrier layer 51 and a quantum dot layer 52 are alternately and repeatedly stacked and has a quantum level (including a superlattice miniband or an intermediate band) formed between the valence band and the conduction band of the matrix material. The barrier layer 51 is composed of an indirect transition semiconductor material.

The quantum dot layer 52 which is a quantum layer has a nanostructure composed of a direct transition semiconductor material. More specifically, the quantum dot layer 52 includes a plurality of quantum dots 53 and a cap 54 of the quantum dots 53. By using the quantum dots 53, the quantum confinement effect can be enhanced due to three-dimensional confinement.

The superlattice semiconductor layer 5 is doped with an impurity. Thus, intersubband transition can be efficiently induced.

The superlattice semiconductor layer 5 may be formed by repeatedly stacking an insertion layer serving as a quantum well together with the quantum dot layer 52 and the barrier layer 51, the insertion layer being made of a material different from the quantum dot layer 52 and the barrier layer 51.

The material of each of the quantum dot layer 52 and the barrier layer 51 is not particularly limited but is a group III-V compound semiconductor. The quantum dot layer 52 is formed of a semiconductor material having a smaller bandgap energy than that of the barrier layer 51. Examples of the material of each of the quantum dot layer 52 and the barrier layer 51 include GaAsₓSb₁₋ₓ, AlSb, InAsₓSb₁₋ₓ, GaₓIn₁₋ₓSb, AlSbₓAs₁₋ₓ, AlAs_{z}Sb_{1-z}, InₓGa₁₋ₓAs, AlₓGa₁₋ₓAs, Al_{y}Ga_{1-y}As_{z}Sb_{1-z}, InₓGa₁₋ₓP, (Al_{y}Ga_{1-y})_{z}In_{1-z}P, GaAsₓP₁₋ₓ, Ga_{y}In_{1-y}As_{z}P_{1-z}, and InₓAl₁₋ₓAs. A mixed crystal material of such a material may be used. In addition, in the materials, x, y, and z have the relationships of 0≦x≦1, 0≦y≦1, and 0≦z≦1, respectively.

The material of each of the quantum dot layer 52 and the barrier layer 51 may be a periodic table group IV semiconductor, a compound semiconductor containing a periodic table group III semiconductor material and a periodic table group V semiconductor material, or a compound semiconductor containing a periodic table group II semiconductor material and a periodic table group VI semiconductor material, or a mixed crystal material thereof. The material of each of the quantum dot layer 52 and the barrier layer 51 may be a chalcopyrite-based material or a semiconductor other than the chalcopyrite-based material.

Examples of a combination of the material of the quantum dots 53 of the quantum dot layer 52/the material of the barrier layer 51 include InₓGa₁₋ₓAs/AlₓGa₁₋ₓAs, InₓGa₁₋ₓAs/InₓGa₁₋ₓP, InₓGa₁₋ₓAs/Ga_{y}In_{1-y}As_{z}P_{1-z}, InₓGa₁₋ₓAs/Al_{y}Ga_{1-y}As_{z}Sb_{1-z}, InₓGa₁₋ₓAs/AlAs_{z}Sb_{1-z}, InₓGa₁₋ₓAs/AlₓGa₁₋ₓSb, InAsₓSb₁₋ₓ/Al_{y}Ga_{1-y}As_{z}Sb_{1-z}, InAsₓSb₁₋ₓ/AlAs_{z}Sb_{1-z}, InAsₓSb₁₋ₓ/AlₓGa₁₋ₓSb, InP/InₓAl₁₋ₓAs, InₓGa₁₋ₓAs/InₓAl₁₋ₓAs, InₓGa₁₋ₓAs/GaAsₓP₁₋ₓ, InₓGa₁₋ₓAs/(Al_{y}Ga_{1-y})_{z}In_{1-z}P, InAsₓSb₁₋ₓ/InₓGa₁₋ₓP, InAsₓSb₁₋ₓ/GaAsₓP₁₋ₓ, GaₓIn₁₋ₓSb/AlSb, and the like. However, in all materials described above, x, y, and z have the relationships of 0≦x≦1, 0≦y≦1, and 0≦z≦1, respectively, and take values within a range in which the material of the barrier layer 51 is an indirect transition semiconductor material, and the material of the quantum dots 53 is a direct transition semiconductor material.

The superlattice semiconductor layer 5 may be an i-type semiconductor layer or, when electromotive force is produced by receiving light, it may be a semiconductor layer containing a p-type impurity or an n-type impurity.

The material of the barrier layer 51 is a wide-gap indirect transition semiconductor material having a bandgap larger than the bandgap of GaAs of 1.42 eV at room temperature (25° C.). The nanostructure (quantum dots 53) of the quantum dot layer 52 is made of a direct transition semiconductor material. When the intersubband transition in the conduction band is utilized, carriers are excited to the conduction band due to transition between Γ points because the nanostructure of the quantum dot layer 52 is made of a direct transition semiconductor material. Then, the carriers exited to the conduction band are relaxed to the lower end of the conduction band of the barrier layer 51 due to relaxation.

Since the barrier layer 51 is made of an indirect transition semiconductor material, electrons are relaxed to an X point, L point, or the like different in wavenumber from the Γ point, and thus electrons and holes are present in difference wavenumber spaces, thereby suppressing recombination of electrons and holes. Therefore, the extraction efficiency of carriers excited from the conduction band quantum level is increased.

Also, the bandgap at room temperature of the indirect transition semiconductor material used for the barrier layer 51 is more than 1.42 eV, and thus the quantum confinement effect is strengthened as compared with a usual typical quantum structure. The “usual typical quantum structure” represents a structure having a bandgap at room temperature of 1.42 eV and using GaAs for the barrier layer 51. There are many indirect transition semiconductor materials having a bandgap at room temperature of more than 1.42 eV. Among these, AlP is an indirect transition semiconductor material having the maximum bandgap (2.52 eV at room temperature). Also, the smallest bandgap of a ternary indirect transition semiconductor material including a group III semiconductor material and a group V semiconductor material is 1.87 eV at room temperature.

When the photoelectric conversion element of the embodiment is used for a solar cell, with increasing the quantum confinement effect, an absorption spectrum using the intersubband transition in the conduction band is shifted to the higher energy side, thereby increasing matching with the solar light spectrum and improving the photoelectric conversion efficiency. When the photoelectric conversion element of the embodiment is used for a photosensor (photodetector), light detection sensitivity is improved with increasing quantum confinement effect.

The quantum confinement strength increases with increasing band offset and can be increased by decreasing the width of the quantum dot layer 52 in the stacking direction or the size of the quantum dots 53. On the other hand, in a quantum dot solar cell using a superlattice miniband (intermediate band), the quantum dots 53 are desired to have smaller variation in size because the superlattice miniband is formed. Even in a quantum dot photosensor (quantum dot photodetector), the quantum dots 53 are desired to have smaller variation in size for improving the selectivity of detection wavelength.

In the embodiment, the quantum dots 53 contain In, and the material desired for the cap 54 contained in the quantum dot layer 52 is InₓGa₁₋ₓAs (0≦x≦1). When the quantum dots 53 contain In, the quantum dots 53 are formed, and then the cap 54 is deposited to a thickness smaller than the height of the quantum dots 53. Then, the height of the quantum dots 53 can be decreased, by annealing, to a height depending on the thickness of the cap 54, thereby allowing the quantum dots 53 to have a uniform height. By decreasing the height of the quantum dots 53, the quantum confinement effect can be increased, and the variation in size of the quantum dots 53 can be decreased. When InₓGa₁₋ₓAs (0≦x≦1) is used as the material of the cap 54 contained in the quantum dot layer 52, the quantum dot layer 52 with high crystallinity can be formed.

Annealing allows the quantum dots 53 to have a conical shape cut at the top, a lens shape, or a shape close to these shapes. Further, surface flatness is remarkably improved after annealing. For example, the quantum dots 53 containing InAs are formed on a GaAs film having a RMS (roughness of root mean square) of 0.14 nm, and then the cap 54 containing GaAs is deposited to a thickness smaller than the height of the quantum dots 53, followed by annealing. In this case, surface RMS is 0.10 nm, that is, surface flatness is improved.

For example, when the substrate 1 is composed of GaAs, an indirect transition semiconductor material having a bandgap of more than 1.42 eV at room temperature other than AlₓGa₁₋ₓAs increases the degree of lattice mismatch with the substrate 1 and easily degrades the surface flatness. When the material of the barrier layer 51 contains Al, surface flatness is easily degraded due to the low migration of Al. However, the surface after the annealing has extremely good flatness, and thus the barrier layer 51 with high crystallinity can be formed.

That is, when a material containing Al or an indirect transition semiconductor material having a high degree of lattice mismatch with the substrate 1 is used as the material of the barrier layer 51, after the quantum dots 53 are formed, the gap 54 containing InₓGa₁₋ₓAs is formed and then annealing is performed. As a result, the quantum confinement effect can be increased by decreasing the height of the quantum dots 53, and variation in size of the quantum dots 53 can be decreased by making the height of the quantum dots 53 uniform. Further, the barrier layer 51 (using the indirect transition semiconductor material) having high crystallinity can be formed.

The indirect transition semiconductor material is a material containing at least Al or P. Therefore, the material has a bandgap of more than 1.42 eV at room temperature.

The substrate 1 is composed of GaAs. When a crystal of the group III-V compound semiconductor material is grown on the substrate 1, a film of high quality can be formed at relatively low cost as long as the substrate 1 is composed of GaAs.

The emitter layer 6 includes a semiconductor containing a p-type impurity, such as GaAs, AlGaAs, InGaP, GaAsP, AlGaAsSb, AlAsSb, GaAsSb, InAlAs, ZnTe, or the like. The emitter layer 6 may be formed by adding a p-type impurity to the same semiconductor material as the barrier layer 51 or adding a p-type impurity to a semiconductor material different from that of the barrier layer 51. The concentration of the p-type impurity in the emitter layer 6 is not particularly limited and is properly determined according to the semiconductor material constituting the emitter layer 6.

The emitter layer 6 may be a thin film formed by a CVD method, a MBE method, or the like. The thickness of the emitter layer 6 is, for example, 20 nm to 3000 nm. However, the thickness of the emitter layer 6 is not particularly limited and is properly determined so that the superlattice semiconductor layer 5 can sufficiently absorb light.

In FIG. 1, the emitter layer 6 is disposed on the light incident side of the superlattice semiconductor layer 5 but may be disposed on the side opposite to the light incident side.

The emitter layer 6 can form a pin junction or pn junction (pn-n junction, pp-n junction, p⁺pn junction, or pnn+ junction) together with the base layer 4 and the superlattice semiconductor layer 5. When a structure having the pin junction or pn junction receives light, electromotive force is generated. That is, the base layer 4, the superlattice semiconductor layer 5, and the emitter layer 6 constitute a photoelectric conversion layer which converts the optical energy of incident light to electric energy.

The window layer 7 includes a semiconductor containing a p-type impurity, which is composed of, for example, Al_{0.9}Ga_{0.1}AS, and has a thickness of, for example, 10 nm to 300 nm.

The contact layer 8 includes a semiconductor containing a p-type impurity, which is composed of, for example, p⁺-GaAS, and has a thickness of, for example, 10 nm to 500 nm.

The p-type electrode 9 can be formed by using a combined material, for example, such as Ti/Pt/Au, Au/Zn, Au/Cr, Ti/Au, Au/Zn/Au, or the like, and has a thickness of, for example, 10 nm to 500 nm.

The n-type electrode 10 can be formed by using a combined material, for example, such as Au/AuGeNi, AuGe/Ni/Au, Au/Ge, Au/Ge/Ni/Au, or the like, and has a thickness of, for example, 10 nm to 500 nm.

The configuration described above may be further provided with a light collecting system, a wavelength conversion film, or the like. For example, a wavelength conversion layer containing a wavelength conversion material which converts the wavelength of incident light and which converts the wavelength light not absorbed by the photoelectric conversion layer can be provided on the back side of the photoelectric conversion layer. In this case, light incident into the wavelength conversion layer is wavelength-converted by the wavelength conversion material and is then emitted from the wavelength conversion layer. The light emitted from the wavelength conversion layer is incident to the photoelectric conversion layer and then subjected to photoelectric conversion. Consequently, the photoelectric conversion efficiency can be improved. In addition, in a configuration further including a metal film provided as a reflection film on the back side of the photoelectric conversion layer, the light wavelength-converted by the wavelength conversion layer and applied to the back side is reflected by the metal film and is incident to the photoelectric conversion layer, and thus the photoelectric conversion efficiency can be further improved.

### <Example of Method for Producing Solar Cell>

An example of a method for producing the solar cell 100 according to the embodiment is described below.

First, the substrate 1 composed of n-GaAs is held in a molecular beam epitaxy (MBE) apparatus. Next, the buffer layer 2 is formed on the substrate 1. An n⁺-GaAs layer having a thickness of 300 nm is formed as the buffer layer 2. By forming the buffer layer 2, the crystallinity of the superlattice semiconductor layer 5 (light absorbing layer) formed on the buffer layer 2 can be improved. Therefore, it is possible to provide a solar cell in which the light receiving efficiency of the superlattice semiconductor layer 5 is secured.

Then, the BSF layer 3 is formed on the buffer layer 2. An n-Al_{0.9}Ga_{0.1}As layer having a thickness of 50 nm is formed as the BSF layer 3. Then, the base layer 4 is formed o the BSF layer 3. An n-Al_{0.8}Ga_{0.2}As layer having a thickness of 2000 nm is formed as the base layer 4.

Then, the superlattice semiconductor layer 5 containing the barrier layer 51 and the quantum dot layer 52 is formed on the base layer 4. The superlattice semiconductor layer 5 can be grown by a method called Stranski-Krastanov (S-K) growth. Specifically, for example, an Al_{0.8}Ga_{0.2}As layer composed of an indirect transition semiconductor material is crystal-grown as the barrier layer 51, and then the quantum dot layer 53 composed of indium arsenide InAs which is a direct transition semiconductor material is formed by a self-organization mechanism. Then, a GaAs layer having a thickness smaller than the height of the quantum dots 53 is crystal-grown as the cap 54 which partially covers the quantum dots 53, followed by annealing. The gap 54 may be formed by using Al_{0.8}Ga_{0.2}As which is the same material as the barrier layer 51. Consequently, the quantum dot layer 52 is formed. Then, crystal growth of an Al_{0.8}Ga_{0.2}As layer as the barrier layer 51 and growth of the quantum dot layer 52 are repeated.

Next, the emitter layer 6 is formed on the superlattice semiconductor layer 5. A p-Al_{0.8}Ga_{0.2}As layer having a thickness of 250 nm is formed as the emitter layer 6. As a result, a pin structure is formed.

Then, the window layer 7 and the contact layer 8 are formed on the emitter layer 6. A p-Al_{0.9}Ga_{0.1}As layer having a thickness of 50 nm is crystal-grown as the window layer 7. A p⁺-GaAs layer having a thickness of 200 nm is crystal-grown as the contact layer 8.

Then, the resultant stack is taken out from the MBE apparatus, and then the p-type electrode 9 is formed on the contact layer 8 by using a photolithography and lift-off technique, and the contact layer 8 is selectively etched by using the p-type electrode 9 as a mask.

The production process described above can use, for example, Si as an n-type dopant and Be as a p-type dopant. In addition, the p-type electrode 9 and the n-type electrode 10 may use Au as a material and may be formed by vacuum vapor deposition using a resistance-heating vapor deposition method.

The solar cell 100 according to the embodiment can be produced by the method described above.

The example described in the embodiment is only an example. That is, the material and production method of each of the substrate 1, the buffer layer 2, the BSF layer 3, the base layer 4, the superlattice semiconductor layer 5, the emitter layer 6, the window layer 7, the contact layer 8, the p-type electrode 9, the n-type electrode 10, the n-type dopant, and the p-type dopant are not limited to those described above.

### [Evaluation Experiment]

A simulation experiment described below was performed for the solar cell 100 according to the embodiment.

A band structure of a quantum structure and light absorption spectrum were simulated by using a 8-band k·p Hamiltonian plane-wave expansion method in consideration of the influence of strain and piezo-electric field effect. The coefficient α of light absorption can be estimated by resolving expression (1) below.

$$α ( ω ) = \frac{{e}^{2}}{2 {n}_{r} {c}_{0} {ɛ}_{0} {m}_{0}^{2} ω {L}_{x} {L}_{y}} \int {dK}_{z} {\sum }_{a , b} {\vert e \cdot {p}_{a , b} \vert}^{2} ( {f}_{a} - {f}_{b} ) G \qquad ( 1 )$$

In the expression (1), e is elementary electric charge, p_{a,b} is a matrix element, a and b are subband Nos., nᵣ is refractive index, c₀ is light velocity, ∈₀ is vacuum dielectric constant, m₀ is electron mass, Lₓ and L_{y} are unit cell sizes in the x direction ((100) direction) and y direction ((010) direction, respectively, K_{z} is superlattice wavenumber, fᵢ (i=a, b) is a distribution function, G is Gaussian broadening due to size variation and composition variation, and ω is light frequency. With respect to light absorption, an x-polarized wave (100) or y-polarized wave (010) in an in-plane direction is regarded as TE polarized light, and z polarized wave (001) in the stacking direction is regarded as TM polarized light.

Calculation of light absorption (intersubband light absorption) through the quantum level in the conduction band is made assuming that the conduction band ground level (or a superlattice miniband or intermediate band) is filled with carriers and that carriers are absent (empty) in a level equivalent to or higher than the first excited level in the conduction band (in the expression (1), (fₐ−f_{b})=1).

The strength of the quantum confinement effect was evaluated by the size of an energy gap between the ground level (e0) and the first excited level (e1) of the conduction band. The larger the energy gap between e0 and e1, the larger the quantum confinement effect. When the energy gap between quantum levels is small, carriers are rapidly relaxed by phonon scattering.

### Experimental Example 1

In a superlattice semiconductor layer 5 of Experimental Example 1, aluminum gallium arsenide (Al_{0.8}Ga_{0.2}As) was used as a base semiconductor material constituting a barrier layer 51, and indium arsenide (InAs) was used as a material of quantum dots 53. Al_{0.8}Ga_{0.2}As is an indirect transition semiconductor material having a bandgap at room temperature of 2.54 eV at a Γ point and 2.10 eV at an X point. That is, the bandgap at room temperature is more than 1.42 eV. InAs is a direct transition semiconductor having a bandgap at room temperature of 0.35 eV at a Γ point.

In the experimental example, AlGaAs was used as the base semiconductor material of the barrier layer 51, and InAs was used as a material of the quantum dots 53a. However, mixed crystal materials such as AlInGaAs, InGaAs, and the like, materials having different compositions, different semiconductor materials, or the like may be used.

The shape of the quantum dots 53 was a lens shape containing a wetting layer of 0.5 nm, and the diameter size in the in-plane direction of the quantum dots 53 was 15 nm. The size (height) of the quantum dots 53 in the stacking direction was each of the 6 types of 8 nm, 6 nm, 4 nm, 2 nm, 1.5 nm, and 1.3 nm. Also, the distance between the quantum dots 53 in the in-plane direction was 20 nm, and the distance between the quantum dots 53 in the stacking direction was 20 nm.

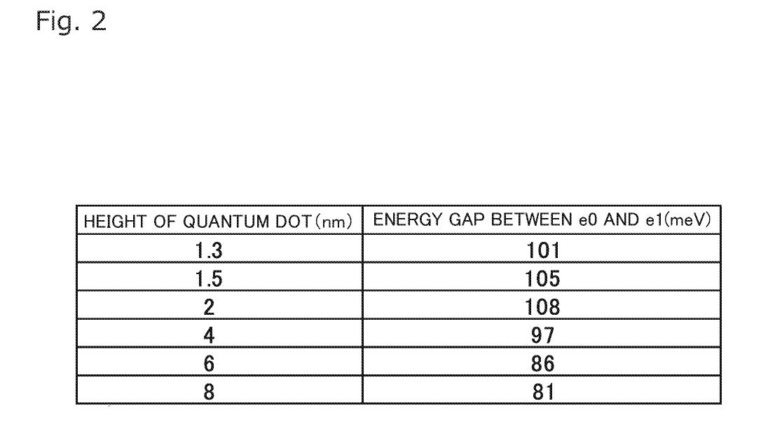

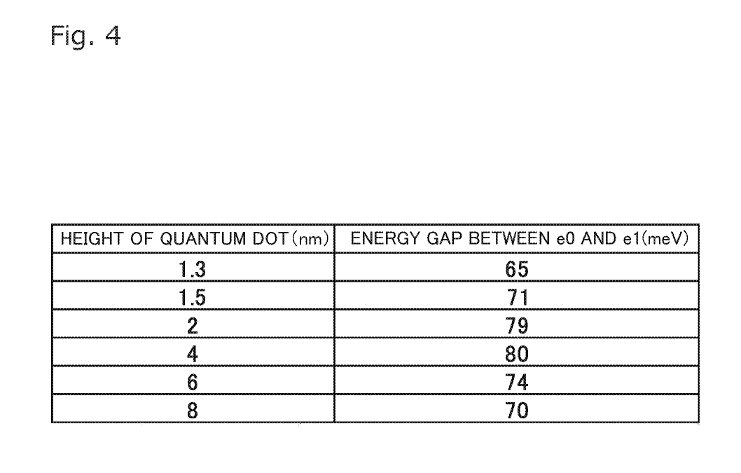

FIG. 2 is a diagram showing a relationship between the height of the quantum dots 53 and the energy gap between e0 and e1 calculated for the superlattice semiconductor layer 5 in Experimental Example 1. FIG. 2 indicates that the energy gap between e0 and e1 increases with decreases in height of the quantum dots 53 within the height range of 2 nm to 8 nm. Also, with the same height of the quantum dots 53, Experimental Example 1 shows a large energy gap between e0 and e1 as compared with Comparative Experimental Example 1 described below (refer to FIG. 4) in which a direct transition semiconductor material was used for the barrier layer 51.

That is, it was confirmed that when Al_{0.8}Ga_{0.2}As which is an indirect transition semiconductor material is used as the base semiconductor material constituting the barrier layer 51, the quantum confinement effect is remarkably increased. Also, since Al_{0.8}Ga_{0.2}As is an indirect transition semiconductor material, recombination of carriers exited to the conduction band is suppressed, and thus the carrier extraction efficiency is improved. Therefore, a photoelectric conversion element with excellent photoelectric conversion efficiency can be provided.

### Comparative Experimental Example 1

A superlattice semiconductor layer of Comparative Experimental Example 1 has a different configuration from the superlattice semiconductor layer 5 of the embodiment described above. Therefore, description is made by adding a to the reference numerals.

In a superlattice semiconductor layer 5a of Comparative Experimental Example 1, gallium arsenide (GaAs) was used as a base semiconductor material constituting a barrier layer 51a, and indium arsenide (InAs) was used as a material of quantum dots 53a. GaAs is a direct transition semiconductor having a bandgap at room temperature of 1.42 eV at F a point. InAs is a direct transition semiconductor having a bandgap at room temperature of 0.35 eV at a Γ point.

In Comparative Experimental Example 1, GaAs was used as the base semiconductor material of the barrier layer 51a, and InAs was used as a material of the quantum dots 53a. However, mixed crystal materials such as InGaAs and the like, different semiconductor materials, or the like may be used.

The shape of the quantum dots 53a was a lens shape containing a wetting layer of 0.5 nm, and the diameter size in the in-plane direction of the quantum dots 53a was 15 nm. The size (height) of the quantum dots 53a in the stacking direction was each of the 6 types of 8 nm, 6 nm, 4 nm, 2 nm, 1.5 nm, and 1.3 nm. Also, the distance between the quantum dots 53a in the in-plane direction was 20 nm, and the distance between the quantum dots 53a in the stacking direction was 20 nm. These conditions were the same as those in Experimental Example 1.

FIG. 4 is a diagram showing a relationship between the height of the quantum dots 53a and the energy gap between e0 and e1 calculated for the superlattice semiconductor layer 5a in Comparative Experimental Example 1. FIG. 4 indicates that the energy gap between e0 and e1 increases with decreases in height of the quantum dots 53a within the height range of 4 nm to 8 nm.

Comparative Experimental Example 1 used a direct transition semiconductor material as the material of the barrier layer 51a. Comparison between FIG. 2 and FIG. 4 indicates that with the same height of the quantum dots 53a (53), Comparative Experimental Example 1 shows a small energy gap between e0 and e1 as compared with Experimental Example 1. That is, a photoelectric conversion element of Experimental Example 1 using the indirect transition semiconductor material as the material of the barrier layer 51 has a higher photoelectric conversion efficiency.

### Experimental Example 2

In Experimental Example 2, the same simulation experiment as in Experimental Example 1 was performed except that in the superlattice semiconductor layer 5 used in Experimental Example 1, the size (height) of the quantum dots 53 in the stacking direction was 1.3 nm, and the distance between the quantum dots 53 in the stacking direction was 4 nm.

In a configuration of a superlattice semiconductor layer 5, aluminum gallium arsenide (Al_{0.8}Ga_{0.2}As) was used as a base semiconductor material constituting a barrier layer 51, and indium arsenide (InAs) was used as a material of quantum dots 53. Al_{0.8}Ga_{0.2}As is an indirect transition semiconductor material having a bandgap at room temperature of 2.54 eV at a Γ point and 2.10 eV at an X point. That is, the bandgap at room temperature is more than 1.42 eV. InAs is a direct transition semiconductor having a bandgap at room temperature of 0.35 eV at a Γ point.

In Experimental Example 2, AlGaAs was used as the base semiconductor material of the barrier layer 51, and InAs was used as a material of the quantum dots 53a. However, mixed crystal materials such as AlInGaAs, InGaAs, and the like, materials having different compositions, different semiconductor materials, or the like may be used.

The shape of the quantum dots 53 was a lens shape containing a wetting layer of 0.5 nm, and the diameter size in the in-plane direction of the quantum dots 53 was 15 nm. The size (height) of the quantum dots 53 in the stacking direction was 1.3 nm. Also, the distance between the quantum dots 53 in the in-plane direction was 20 nm, and the distance between the quantum dots 53 in the stacking direction was 4 nm.

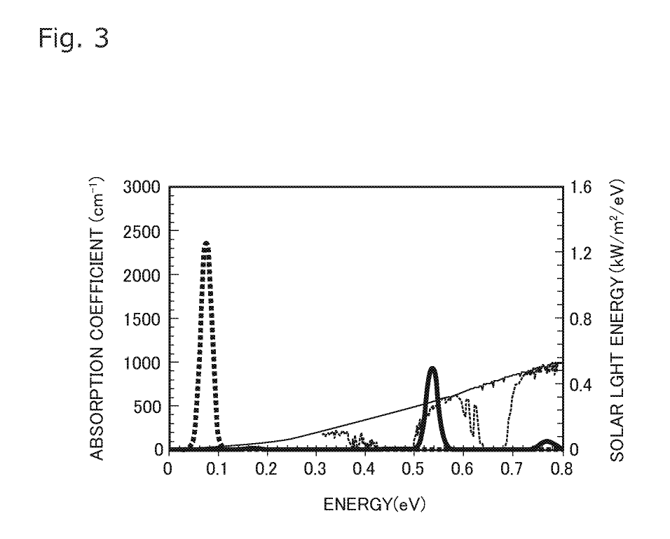

FIG. 3 is a diagram showing an intersubband light absorption spectrum of the conduction band calculated for the superlattice semiconductor layer 5 in Experimental Example 2. In FIG. 3, the abscissa indicates energy (eV), the left-side ordinate indicates absorption coefficient (cm⁻¹), and the right-hand ordinate indicates solar light energy (kW/m²/eV). In FIG. 3, TE polarized light absorption is shown by a thick solid line, TM polarized light absorption is shown by a thick broken line, a solar light spectrum under AM 0 is shown by a thin solid line, and a solar light spectrum of under AM 1.5G is shown by a thin broken line.

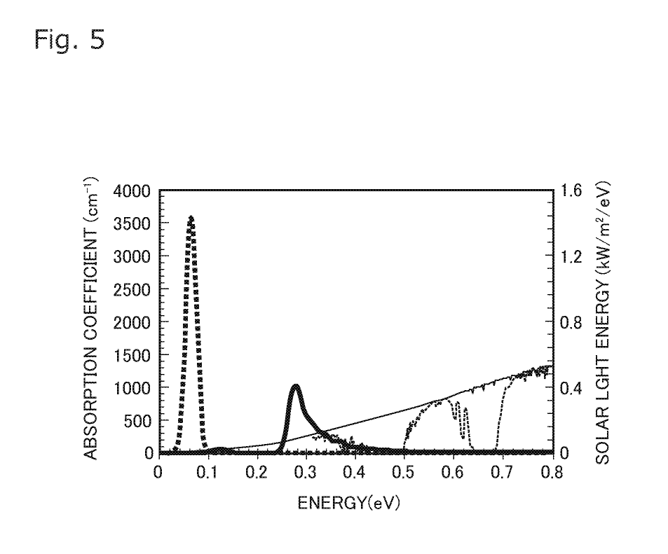

Comparative Experimental Example 2 described below used GaAs (bandgap at room temperature of 1.42 eV) which was a direct transition semiconductor for a barrier layer. Comparison with FIG. 5 showing the results of Comparative Experimental Example 2 indicates that in Experimental Example 2, the quantum confinement effect is increased by using a wide-gap material for the barrier layer 51, and thus a light absorption spectrum is shifted to the higher energy side, thereby improving matching with the solar light spectrum. Also, since Al_{0.8}Ga_{0.2}As is an indirect transition semiconductor material, recombination of carriers exited to the conduction band is suppressed, and thus the carrier extraction efficiency is improved. Therefore, a photoelectric conversion element with excellent photoelectric conversion efficiency can be provided.

### Comparative Experimental Example 2

In Comparative Experimental Example 2, the same simulation experiment as Comparative Experimental Example 1 was performed except that in the superlattice semiconductor layer 5 used in Comparative Experimental Example 1, the size (height) of the quantum dots 53 in the stacking direction was 1.3 nm, and the distance between the quantum dots 53 in the stacking direction was 4 nm. The size (height) of the quantum dots 53 in the stacking direction and the distance between the quantum dots 53 in the stacking direction were the same as in Experimental Example 2. Comparative Experimental Example 2 is different from Experimental Example 2 in the semiconductor material used for the barrier layer.

A superlattice semiconductor layer of Comparative Experimental Example 2 has a configuration different from that of the superlattice semiconductor layer 5 of the embodiment described above. Therefore, description is made by adding b to the reference numerals.

In a superlattice semiconductor layer 5b of Comparative Experimental Example 2, gallium arsenide (GaAs) was used as a base semiconductor material constituting a barrier layer 51b, and indium arsenide (InAs) was used as a material of quantum dots 53b. GaAs is a direct transition semiconductor having a bandgap at room temperature of 1.42 eV at a Γ point. InAs is a direct transition semiconductor having a bandgap at room temperature of 0.35 eV at a Γ point.

Although, in Comparative Experimental Example 2, GaAs was used as the base semiconductor material of the barrier layer 51b, and InAs was used as a material of the quantum dots 53b, mixed crystal materials such as InGaAs, different semiconductor materials, or the like may be used.

The shape of the quantum dots 53b was a lens shape containing a wetting layer of 0.5 nm, and the diameter size in the in-plane direction of the quantum dots 53b was 15 nm. The size (height) of the quantum dots 53b in the stacking direction was 1.3 nm. Also, the distance between the quantum dots 53b in the in-plane direction was 20 nm, and the distance between the quantum dots 53b in the stacking direction was 4 nm. These conditions were the same as in Experimental Example 2.

FIG. 5 is a diagram showing an intersubband light absorption spectrum of the conduction band calculated for the superlattice semiconductor layer 5b in Comparative Experimental Example 2. In FIG. 5, the abscissa indicates energy (eV), the left-side ordinate indicates absorption coefficient (cm⁻¹), and the right-hand ordinate indicates solar light energy (kW/m²/eV). In FIG. 5, TE polarized light absorption is shown by a thick solid line, TM polarized light absorption is shown by a thick broken line, a solar light spectrum under AM 0 is shown by a thin solid line, and a solar light spectrum of under AM 1.5G is shown by a thin broken line. FIG. 5 indicates that in the comparative Experimental Example, the light absorption spectrum has low matching with the solar light spectrum.

### Experimental Example 3

In Experimental Example 3, the same simulation experiment as in Experimental Example 1 was performed except that in the superlattice semiconductor layer 5 used in Experimental Example 1, the size (height) of the quantum dots 53 in the stacking direction was 4 nm, and the base semiconductor material constituting the barrier layer 51 was changed.

In a configuration of a superlattice semiconductor layer 5, indium gallium phosphide (In_{0.1}Ga_{0.9}P) was used as a base semiconductor material constituting a barrier layer 51, and indium arsenide (InAs) was used as a material of quantum dots 53. In_{0.1}Ga_{0.9}P is an indirect transition semiconductor having a bandgap at room temperature of 2.58 eV at a Γ point and 2.25 eV at an X point. That is, the bandgap at room temperature is more than 1.42 eV. InAs is a direct transition semiconductor having a bandgap at room temperature of 0.35 eV at a Γ point.

In Experimental Example 3, InGaP was used as the base semiconductor material of the barrier layer 51, and InAs was used as a material of the quantum dots 53a. However, mixed crystal materials such as AlInGaP, InGaAs, and the like, materials having different compositions, different semiconductor materials, or the like may be used.

The shape of the quantum dots 53 was a lens shape containing a wetting layer of 0.5 nm, and the diameter size in the in-plane direction of the quantum dots 53 was 15 nm. The size (height) of the quantum dots 53 in the stacking direction was 4 nm. Also, the distance between the quantum dots 53 in the in-plane direction was 20 nm, and the distance between the quantum dots 53 in the stacking direction was 20 nm.

The energy gap between e0 and e1 calculated for the superlattice semiconductor layer 5 in the Experimental Example is 92 meV. On the other hand, in Comparative Experimental Example 1 (refer to FIG. 4) in which the size (height) of the quantum dots 53a in the stacking direction was 4 nm, the energy gap between e0 and e1 is 80 meV. Therefore, in the Experimental Example, the energy gap between e0 and e1 is greatly large as compared with in Comparative Experimental Example 1 under the condition of the same height of the quantum dots 53.

That is, it was confirmed that the quantum confinement effect is greatly increased by using In_{0.1}Ga_{0.9}P which is an indirect semiconductor material as the base semiconductor material of the barrier layer 51. Also, since In_{0.1}Ga_{0.9}P is an indirect transition semiconductor material, recombination of carriers exited to the conduction band is suppressed, and thus the carrier extraction efficiency is improved. Therefore, a photoelectric conversion element with excellent photoelectric conversion efficiency can be provided.

### Experimental Example 4

In Experimental Example 4, the same simulation experiment as in Experimental Example 1 was performed except that in the superlattice semiconductor layer 5 used in Experimental Example 1, the size (height) of the quantum dots 53 in the stacking direction was 4 nm, and the base semiconductor material constituting the barrier layer 51 was changed.

In a configuration of a superlattice semiconductor layer 5, gallium arsenide phosphide (GaAs_{0.1}P_{0.9}) was used as a base semiconductor material constituting a barrier layer 51, and indium arsenide (InAs) was used as a material of quantum dots 53. GaAs_{0.1}P_{0.9} is an indirect transition semiconductor having a bandgap at room temperature of 2.62 eV at a Γ point and 2.21 eV at an X point. That is, the bandgap at room temperature is more than 1.42 eV. InAs is a direct transition semiconductor having a bandgap at room temperature of 0.35 eV at a Γ point.

In Experimental Example 4, GaAsP was used as the base semiconductor material of the barrier layer 51, and InAs was used as a material of the quantum dots 53a. However, liquid crystal materials such as AlGaAsP, InGaAs, and the like, materials having different compositions, different semiconductor materials, or the like may be used.

The shape of the quantum dots 53 was a lens shape containing a wetting layer of 0.5 nm, and the diameter size in the in-plane direction of the quantum dots 53 was 15 nm. The size (height) of the quantum dots 53 in the stacking direction was 4 nm. Also, the distance between the quantum dots 53 in the in-plane direction was 20 nm, and the distance between the quantum dots 53 in the stacking direction was 20 nm.

The energy gap between e0 and e1 calculated for the superlattice semiconductor layer 5 in the experimental example is 92 meV. On the other hand, in Comparative Experimental Example 1 (refer to FIG. 4) in which the size (height) of the quantum dots 53a in the stacking direction was 4 nm, the energy gap between e0 and e1 is 80 meV. Therefore, in the Experimental Example, the energy gap between e0 and e1 is greatly large as compared with in Comparative Experimental Example 1 under the condition of the same height of the quantum dots 53.

That is, it was confirmed that the quantum confinement effect is increased by using GaAs_{0.1}P_{0.9} as the base semiconductor material constituting the barrier layer 51. Also, since GaAs_{0.1}P_{0.9} is an indirect transition semiconductor, recombination of carriers exited to the conduction band is suppressed, and thus the carrier extraction efficiency is improved. Therefore, a photoelectric conversion element with excellent photoelectric conversion efficiency can be provided.

### <Modified Configuration Example 1 of Photoelectric Conversion Element>

The photoelectric conversion element may be a photoelectric conversion element transferred to another substrate. For example, a photoelectric conversion element having flexibility can be produced by transfer to a flexible substrate.

Specifically, an epitaxial layer grown on a substrate is separated from the substrate and then transferred to a flexible substrate on which an electrode layer has been formed. The electrode layer may be formed after the transfer. This structure permits the production of a photoelectric conversion element with high flexibility. Also, the structure permits the reuse of an epitaxial growth substrate, leading to a decrease in cost. The substrate subjected to transfer may be a metal foil or the like, not the flexible substrate.

### <Modified Configuration Example 2 of Photoelectric Conversion Element>

A solar cell serving as a photoelectric conversion element may be configured to be combined with a luminescence converter. The luminescence converter is configured to include a wavelength conversion material, which is mixed with glass, a resin, or the like for fixing the wavelength conversion material, followed by molding. For example, the luminescence converter includes a wavelength conversion layer containing one or a plurality of wavelength conversion materials, and a photoelectric conversion layer provided on the side surface of the luminescence converter. Solar light incident on the wavelength conversion layer is condensed and wavelength-converted and is then incident on the photoelectric conversion layer. Thus, an improvement in the photoelectric conversion efficiency of the solar cell can be expected.

In the luminescence converter, solar light incident on a surface is repeatedly wavelength-converted and radiated in the luminescence converter, totally reflected from the surface and the back, and finally emitted as condensed and wavelength-converted solar light from the four edge surfaces of a rectangular parallelepiped. The photoelectric conversion efficiency of the solar cell can be improved by providing the photoelectric conversion layer on each of the four edge surfaces of the luminescence converter. Also, the structure can be formed by using the solar cell in an amount equivalent to about the edge area, and thus the amount and cost of the materials used can be decreased. Further, the solar cell is light-weighted and thus can be attached to a window or a construction material or can be mounted on a roof, and can be used regardless of place.

The embodiment described above is only an example for carrying out the present disclosure. Therefore, the present disclosure is not limited to the embodiment described above, and the embodiment described above can be properly modified without deviating from the scope of the present disclosure.

A photoelectric conversion element having a quantum structure using an indirect transition semiconductor material according to an embodiment of the present disclosure includes a superlattice semiconductor layer in which a barrier layer and a quantum layer are alternately and repeatedly stacked for improving the photoelectric conversion efficiency. The barrier layer is composed of an indirect transition semiconductor material, and the quantum layer has a nano-structure composed of a direct transition semiconductor material, the indirect transition semiconductor material having a bandgap of more than 1.42 eV at room temperature.

In the embodiment, an example in which the photoelectric conversion element is applied to a solar cell is described. However, besides the solar cell, the photoelectric conversion element can be applied to a semiconductor optical amplifier which amplified an optical signal by stimulated emission of carriers stored in a photodiode or semiconductor, a quantum dot infrared sensor which detects infrared light by exciting carriers with the photon energy of infrared light, and the like.

In the embodiment described above, an n-type semiconductor layer is used as the base layer 4, and a p-type semiconductor layer is used as the emitter layer 6. However, a p-type semiconductor layer may be used as the base layer 4, and an n-type semiconductor layer may be used as the emitter layer 6.

The present disclosure contains subject matter related to that disclosed in Japanese Priority Patent Application JP 2016-003963 filed in the Japan Patent Office on Jan. 12, 2016, the entire contents of which are hereby incorporated by reference.

It should be understood by those skilled in the art that various modifications, combinations, sub-combinations and alterations may occur depending on design requirements and other factors insofar as they are within the scope of the appended claims or the equivalents thereof.

What is claimed is:

1. A photoelectric conversion element having a quantum structure using an indirect transition semiconductor material, the photoelectric conversion element utilizing intersubband transition in a conduction band and comprising:
a photoelectric conversion layer having a quantum structure; and
a superlattice semiconductor layer in which a barrier layer and a quantum layer are alternately and repeatedly stacked,
wherein the barrier layer includes an indirect transition semiconductor material;
the quantum layer has a nano-structure including a direct transition semiconductor material; and
the indirect transition semiconductor material has a bandgap of more than 1.42 eV at room temperature.

2. The photoelectric conversion element having a quantum structure using an indirect transition semiconductor material according to claim 1, wherein the superlattice semiconductor layer is doped with an impurity.

3. The photoelectric conversion element having a quantum structure using an indirect transition semiconductor material according to claim 1, wherein the quantum layer is a quantum dot layer having a quantum dot.

4. The photoelectric conversion element having a quantum structure using an indirect transition semiconductor material according to claim 3,
wherein the quantum dot layer contains the quantum dot and a cap;
the quantum dot contains In; and
the cap contains InₓGa₁₋ₓAs (0≦x≦1).

5. The photoelectric conversion element having a quantum structure using an indirect transition semiconductor material according to claim 1, wherein the indirect transition semiconductor material contains at least one of Al and P.

6. The photoelectric conversion element having a quantum structure using an indirect transition semiconductor material according to claim 1, further comprising substrate composed of GaAs.
